(19) United States
(12) Patent Application Publication
(10) Pub. No.: US 2015/0021698 A1
(43) Pub. Date: Jan. 22, 2015

(54) Intrinsic Channel Planar Field Effect Transistors Having Multiple Threshold Voltages

(71) Applicant: International Business Machines Corporation, Armonk, NY (US)

(72) Inventors: Takashi Ando, Tuckahoe, NY (US); Ramachandra Divakaruni, Ossining, NY (US); Balaji Kannan, Flshkill, NY (US); Siddarth A. Krishnan, Peekskill, NY (US); Arvind Kumar, Chappaqua, NY (US); Unoh Kwon, Fishkill, NY (US); Barry P. Linder, Hastings-on-Hudson, NY (US); Vijay Narayanan, New York, NY (US)

(21) Appl. No.: 13/945,086

(22) Filed: Jul. 18, 2013

(51) Int. Cl. H01L 27/088; H01L 21/28

(52) U.S. Cl. CPC H01L 27/0886; H01L 21/28008
USPC 257/368; 438/591

(57) ABSTRACT

Intrinsic channels one or more intrinsic semiconductor materials are provided in a semiconductor substrate. A high dielectric constant (high-k) gate dielectric layer is formed on the intrinsic channels. A patterned diffusion barrier metallic nitride layer is formed. A threshold voltage adjustment oxide layer is formed on the physically exposed portions of the high-k gate dielectric layer and the diffusion barrier metallic nitride layer. An anneal is performed to drive in the material of the threshold voltage adjustment oxide layer to the interface between the intrinsic channel(s) and the high-k gate dielectric layer, resulting in formation of threshold voltage adjustment oxide portions. At least one work function material layer is formed, and is patterned with the high-k gate dielectric layer and the threshold voltage adjustment oxide portions to form multiple types of gate stacks.

### RELATED APPLICATIONS

The present application is related to a copending U.S. patent application Ser. No. ______ (Attorney Docket No. FIS920130045US1; 29852), the entire contents of which are incorporated herein by reference.

### BACKGROUND

The present disclosure generally relates to semiconductor devices, and particularly to planar field effect transistors having different threshold voltages through gate dielectric stack modification, and methods of manufacturing the same.

Advanced semiconductor chips employ multiple types of field effect transistors having different threshold voltages, on-current per unit width, and off-current per unit width. Field effect transistors having a high threshold voltage are typically called “low power” devices, which have a low on-current and a low off-current. Field effect transistors having a low threshold voltage are called “high performance” devices, which has a high on-current and a high off-current. By employing a mixture of low power devices and high performance devices, a semiconductor chip may provide optimal performance at an optimal power consumption level.

Use of a doped channel for small scale field effect transistors results in stochastic variations in the dopant concentration, and resulting variations in the threshold voltages. Thus, methods of controlling threshold voltages without resorting to control of channel doping are desired.

### SUMMARY

Intrinsic channels containing one or more intrinsic semiconductor materials are provided in a semiconductor substrate. A high dielectric constant (high-k) gate dielectric layer is formed on the intrinsic channels. A diffusion barrier metallic nitride layer is deposited and patterned to block at least one portion of the high-k gate dielectric layer, while physically exposing at least another portion of the high-k gate dielectric layer. A threshold voltage adjustment oxide layer is formed on the physically exposed portions of the high-k gate dielectric layer and the diffusion barrier metallic nitride layer. An anneal is performed to drive in the material of the threshold voltage adjustment oxide layer to the interface between the intrinsic channel(s) and the high-k gate dielectric layer, resulting in formation of threshold voltage adjustment oxide portions. At least one work function material layer is formed, and is patterned with the high-k gate dielectric layer and the threshold voltage adjustment oxide portions to form multiple types of gate stacks.

According to an aspect of the present disclosure, a semiconductor structure contains a field effect transistor including a first gate stack, a second field effect transistor including a second gate stack, and a third field effect transistor including a third gate stack. The first gate stack contains a first high dielectric constant (high-k) dielectric portion and a first gate electrode contacting the first high-k dielectric portion. The first high-k dielectric portion includes a first high-k dielectric material having a dielectric constant greater than 4.0 and overlies a first semiconductor channel region. The second gate stack contains a threshold voltage adjustment oxide portion, a second high-k dielectric portion including the first high-k dielectric material, and a second gate electrode contacting the second high-k dielectric portion. The threshold voltage adjustment oxide portion includes a second high-k dielectric material having a dielectric constant greater than 4.0 and different from the first high-k dielectric material and overlies a second semiconductor channel region. The third gate stack contains at least a third high-k dielectric portion including the first high-k dielectric material and a third gate electrode contacting the third high-k dielectric portion. The first field effect transistor and the third field effect transistor are field effect transistors of complementary types.

According to another aspect of the present disclosure, a method of forming a semiconductor structure is provided. A high dielectric constant (high-k) dielectric layer including a first high-k dielectric material is formed on a plurality of semiconductor material regions in a semiconductor substrate. A diffusion barrier metallic nitride layer is formed and patterned such that at least one portion of the high-k dielectric layer is physically exposed while at least another portion of the high-k dielectric layer is covered by a patterned portion of the diffusion barrier metallic nitride layer. A threshold voltage adjustment oxide layer is formed over the high-k dielectric layer and the patterned diffusion barrier metallic nitride layer. The threshold voltage adjustment oxide layer includes a second high-k dielectric material. Diffusion of the second high-k dielectric material through the first high-k dielectric material is induced by an anneal. The patterned diffusion barrier metallic nitride layer blocks diffusion of the second high-k dielectric material therethrough, and at least one threshold voltage adjustment oxide portion is formed directly on at least one of the plurality of semiconductor material regions. The patterned diffusion barrier metallic nitride layer is removed. At least one conductive material layer is formed on the high-k dielectric layer. Gate stacks are formed by patterning the at least one conductive material layer, the high-k dielectric layer, and the at least one threshold voltage adjustment oxide portion.

### BRIEF DESCRIPTION OF SEVERAL VIEWS OF THE DRAWINGS

FIG. 1 is a vertical cross-sectional view of a first exemplary semiconductor structure after formation of ground plane portions and shallow trench isolation structures according to a first embodiment of the present disclosure.

FIG. 2 is a vertical cross-sectional view of the first exemplary semiconductor structure after formation of disposable gate stacks, gate spacers, and source and drain regions according to a first embodiment of the present disclosure.

FIG. 3 is a vertical cross-sectional view of the first exemplary semiconductor structure after removal of disposable gate stacks and formation of gate cavities according to the first embodiment of the present disclosure.

FIG. 4 is a vertical cross-sectional view of the first exemplary semiconductor structure after deposition of a high dielectric constant (high-k) gate dielectric layer and a diffusion barrier metallic nitride layer according to the first embodiment of the present disclosure.

FIG. 5 is a vertical cross-sectional view of the first exemplary semiconductor structure after patterning of the diffusion barrier metallic nitride layer according to the first embodiment of the present disclosure.

FIG. 6 is a vertical cross-sectional view of the first exemplary semiconductor structure after deposition of a threshold voltage adjustment oxide layer and optional deposition of a cap material layer according to the first embodiment of the present disclosure.

FIG. 7 is a vertical cross-sectional view of the first exemplary semiconductor structure after an anneal that forms threshold voltage adjust oxide portions between intrinsic channels and the high-k gate dielectric layer and after removal of the optional cap material layer and the patterned diffusion barrier metallic nitride layer according to the first embodiment of the present disclosure.

FIG. 8 is a vertical cross-sectional view of the first exemplary semiconductor structure after deposition and patterning of a first work function material layer and deposition of a second work function material layer according to the first embodiment of the present disclosure.

FIG. 9 is a vertical cross-sectional view of the first exemplary semiconductor structure after planarization of work function material layers and dielectric material layers from above a top surface of a planarization dielectric layer according to the first embodiment of the present disclosure.

FIG. 10 is a vertical cross-sectional view of the first exemplary semiconductor structure after formation of a contact level dielectric layer and various contact via structures according to the first embodiment of the present disclosure.

FIG. 11 is a vertical cross-sectional view of a variation of the first exemplary semiconductor structure according to a second embodiment of the present disclosure.

FIG. 12 is a vertical cross-sectional view of a second exemplary semiconductor structure after deposition of a high dielectric constant (high-k) gate dielectric layer and a diffusion barrier metallic nitride layer according to the second embodiment of the present disclosure.

FIG. 13 is a vertical cross-sectional view of the second exemplary semiconductor structure after patterning of the diffusion barrier metallic nitride layer according to the second embodiment of the present disclosure.

FIG. 14 is a vertical cross-sectional view of the second exemplary semiconductor structure after deposition of a threshold voltage adjustment oxide layer and optional deposition of a cap material layer according to the second embodiment of the present disclosure.

FIG. 15 is a vertical cross-sectional view of the second exemplary semiconductor structure after an anneal that forms threshold voltage adjust oxide portions between intrinsic channels and the high-k gate dielectric layer according to the second embodiment of the present disclosure.

FIG. 16 is a vertical cross-sectional view of the second exemplary semiconductor structure after deposition and patterning of a second work function material layer and deposition of a second work function material layer according to the second embodiment of the present disclosure.

FIG. 17 is a vertical cross-sectional view of the second exemplary semiconductor structure after formation of gate stacks according to a second embodiment of the present disclosure.

FIG. 18 is a vertical cross-sectional view of the second exemplary semiconductor structure after formation of gate spacers and source and drain regions according to the second embodiment of the present disclosure.

FIG. 19 is a vertical cross-sectional view of the second exemplary semiconductor structure after formation of a contact level dielectric layer and various contact via structures according to the second embodiment of the present disclosure.

FIG. 20 is a vertical cross-sectional view of a variation of the second exemplary semiconductor structure according to a variation of the second embodiment of the present disclosure.

### DETAILED DESCRIPTION

As stated above, the present disclosure relates to planar field effect transistors having different threshold voltages through gate dielectric stack modification, and methods of manufacturing the same. Aspects of the present disclosure are now described in detail with accompanying figures. Like and corresponding elements are referred to by like reference numerals. Proportions of various elements in the accompanying figures are not drawn to scale. As used herein, ordinals such as “first” and “second” are employed merely to distinguish similar elements, and different ordinals may be employed to designate a same element in the specification and/or claims.

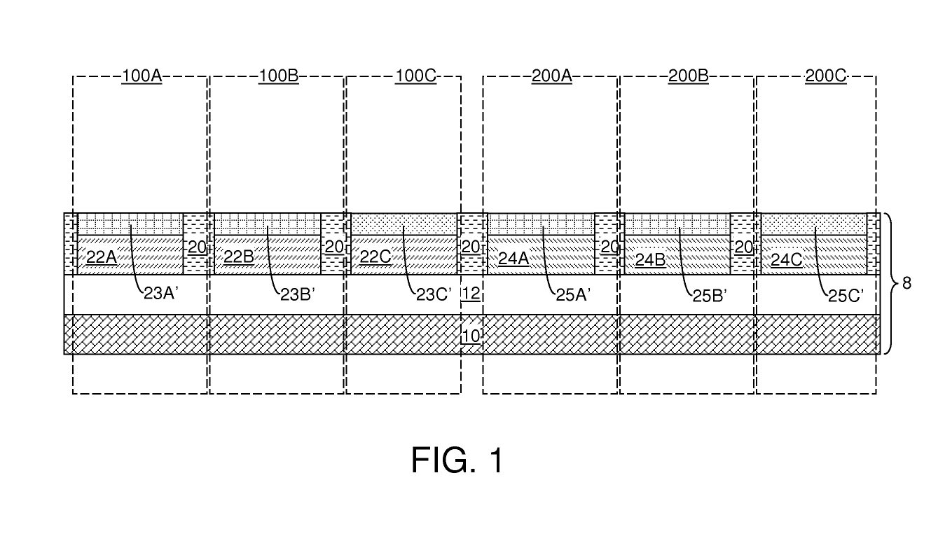

Referring to FIG. 1, a first exemplary semiconductor structure according to a first embodiment of the present disclosure includes a semiconductor substrate 8. The semiconductor substrate 8 includes a semiconductor material layer having a physically exposed top surface. In one embodiment, the semiconductor substrate 8 can be a semiconductor-on-insulator (SOI) substrate including a vertical stack, from bottom to top, of a handle substrate 10, a buried insulator layer 12, and a top semiconductor layer. The top semiconductor layer can include a same semiconductor material throughout, or can include a plurality of regions including different semiconductor materials. Alternatively, the semiconductor substrate 8 can be a bulk semiconductor substrate including a top portion that is structurally and functionally equivalent to the top semiconductor layer of an SOI substrate and includes various doped wells configured to provide electrical isolation among different device regions.

The first exemplary semiconductor structure can include various device regions. In a non-limiting illustrative example, the first exemplary semiconductor structure can include a first device region 100A, a second device region 100B, a third device region 100C, a fourth device region 200A, a fifth device region 200B, and a sixth device region 200C. Additional device regions (not shown) can be provided for the purpose of forming additional devices. Further, multiple instances of devices can be formed in each of the device regions (100A, 100B, 100C, 200A, 200B, 200C). Each of the device regions (100A, 100B, 100C, 200A, 200B, 200C) can be electrically isolated from one another by various shallow trench isolation structures 20, which can include a dielectric material such as silicon oxide and/or silicon nitride. The first-type device regions (100A, 100B, 100C) can be employed to form first-type field effect transistors, and the second-type device regions (200A, 200B, 200C) can be employed to form second-type field effect transistors. Thus, the first, second, and third field effect transistors can be first-type field effect transistors, and the fourth, fifth, and sixth field effect transistors can be second-type field effect transistors. In one embodiment, the first-type can be p-type and the second-type can be n-type. In another embodiment, the first-type can be n-type and the second-type can be p-type.

As used herein, the term “first-type” and the “second-type” are employed to differentiate between elements employed for p-type devices and elements employed for n-type devices. In one embodiment, “first-type” elements can be elements for p-type planar field effect transistors and “second-type” elements can be elements for n-type planar field effect transistors. Alternatively, “first-type” elements can be elements for n-type planar field effect transistors and “second-type” elements can be elements for p-type planar field effect transistors. First-type field effect transistors and second-type field effect transistors are field effect transistors of complementary types, i.e., opposite types that can be employed to form complementary metal oxide semiconductor (CMOS) devices. Thus, p-type field effect transistors are field effect transistors of the complementary type with respect to n-type field effect transistors, and vice versa.

In one embodiment, each of device regions (100A, 100B, 100C, 200A, 200B, 200C) can include a vertical stack, from bottom to top, of a doped semiconductor material portion and an intrinsic semiconductor material portion. Within each device region, the doped semiconductor material portion and the intrinsic semiconductor material portion can include a same semiconductor material and can differ in composition only by the presence of electrical dopants (p-type dopants or n-type dopants) in the doped semiconductor material portion and the absence of electrical dopants in the intrinsic semiconductor material portion. Further, within each device region (100A, 100B, 100C, 200A, 200B, 200C), the entirety of the stack of the doped semiconductor material portion and the intrinsic semiconductor material portion can include a same single crystalline semiconductor material.

For example, the first device region 100A can include a vertical stack of a first doped semiconductor material region 22A in contact with a bottom surface of a first intrinsic semiconductor material region 23A′, a second device region 100B can include a vertical stack of a second doped semiconductor material region 22B in contact with a bottom surface of a second intrinsic semiconductor material region 23B′, a third device region 100C can include a vertical stack of a third doped semiconductor material region 22B in contact with a bottom surface of a third intrinsic semiconductor material region 23B′, a fourth device region 200A can include a vertical stack of a fourth doped semiconductor material region 24A in contact with a bottom surface of a fourth intrinsic semiconductor material region 25A′, a fifth device region 200B can include a vertical stack of a fifth doped semiconductor material region 24B in contact with a bottom surface of a fifth intrinsic semiconductor material region 25B′, and a sixth device region 200C can include a vertical stack of a sixth doped semiconductor material region 24B in contact with a bottom surface of a sixth intrinsic semiconductor material region 25B′.

In one embodiment, the first doped semiconductor material region 22A, the second doped semiconductor material region 22B, and the third doped semiconductor material region 22C can include dopants of a first conductivity type, and the fourth doped semiconductor material region 24A, the fifth doped semiconductor material region 24B, and the sixth doped semiconductor material region 24C can include dopants of a second conductivity type, which is the opposite of the first conductivity type. For example, the first conductivity type can be p-type and the second conductivity type can be n-type, or vice versa.

Each vertical stack of a doped semiconductor material region (one of 22A, 23B, 22C, 24A, 24B, 24C) and an intrinsic semiconductor material region (one of 23A′, 23B′, 23C′, 25A′, 25B′, 25C′) can include a semiconductor material that is independently selected from silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. In one embodiment, each vertical stack of a doped semiconductor material region (one of 22A, 23B, 22C, 24A, 24B, 24C) and an intrinsic semiconductor material region (one of 23A′, 23B′, 23C′, 25A′, 25B′, 25C′) can include a semiconductor material that is independently selected from single crystalline silicon, a single crystalline silicon-germanium alloy, a single crystalline silicon-carbon alloy, and a single crystalline silicon-germanium-carbon alloy. As used herein, a “semiconductor material” of an element refers to all elemental or compound semiconductor materials in the element excluding the electrical dopants therein. The semiconductor material within each vertical stack can be the same throughout the entirety of the vertical stack.

In a non-limiting illustrative embodiment, the vertical stack of the first doped semiconductor material region 22A and the first intrinsic semiconductor material region 23A′, the vertical stack of the second doped semiconductor material region 22B and the second intrinsic semiconductor material region 23B′, the vertical stack of the fourth doped semiconductor material region 24A and the fourth intrinsic semiconductor material region 25A′, and the vertical stack of the fifth doped semiconductor material region 24B and the fifth intrinsic semiconductor material region 25B′ can include single crystalline silicon as the semiconductor material. The vertical stack of the third doped semiconductor material region 22B and the third intrinsic semiconductor material region 23B′ can include one of a single crystalline silicon-germanium alloy or a silicon carbon alloy as the semiconductor material. The vertical stack of the sixth doped semiconductor material region 24B and the sixth intrinsic semiconductor material region 25B′ can include another of a single crystalline silicon-germanium alloy or a silicon carbon alloy as the semiconductor material.

The thickness of each doped semiconductor material region (one of 22A, 22B, 22C, 24A, 24B, 24C) can be in a range from 10 nm to 300 nm, although lesser and greater thicknesses can also be employed. The thickness of each intrinsic semiconductor material region (one of 23A′, 23B′, 23C′, 25A′, 25B′, 25C′) can be in a range from 10 nm to 300 nm, although lesser and greater thicknesses can also be employed.

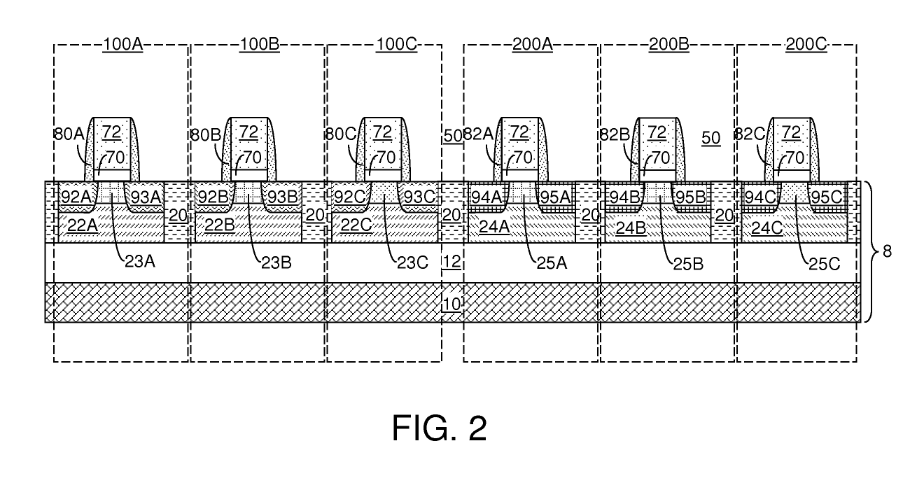

Referring to FIG. 2, a disposable dielectric layer and a disposable gate material layer are deposited and lithographically patterned to form disposable gate structures. In one embodiment, at least one disposable gate structure can be formed in each device region (100A, 100B, 100C, 200A, 200B, 200C). Each disposable gate stack can include a vertical stack of a disposable dielectric portion 70 and a disposable gate material portion 72. Each disposable dielectric portion 70 is a remaining portion of the disposable dielectric layer after the lithographic patterning, and each disposable gate material portion 72 is a remaining portion of the disposable gate material layer after the lithographic patterning. The disposable dielectric portions 70 can include a dielectric material such as silicon oxide, silicon nitride, and/or silicon oxynitride. The disposable gate material portions 72 can include a conductive material, semiconductor material, and/or a dielectric material that is different from the material of the disposable dielectric portions 70. The conductive material can be an elemental metal or a metallic compound, the semiconductor material can be silicon, germanium, a III-V compound semiconductor material, or an alloy or a stack thereof, and the dielectric material can be silicon oxide, silicon nitride, or porous or non-porous organosilicate glass (OSG).

Dielectric gate spacers can be formed on sidewalls of each of the disposable gate structures (70, 72), for example, by deposition of a conformal dielectric material layer and an anisotropic etch. The dielectric gate spacers can include, for example, a first gate spacer 80A formed in the first device region 100A, a second gate spacer 80B formed in the second device region 100B, a third gate spacer 80C formed in the third device region 100C, a fourth gate spacer 80A formed in the fourth device region 200A, a fifth gate spacer 80B formed in the fifth device region 200B, and a sixth gate spacer 80C formed in the sixth device region 200C.

Electrical dopants of the second conductivity type can be implanted into the first, second, and third device regions (100A, 100B, 100C) to form various source and drain regions, which can include, for example, a first source region 92A, a first drain region 93A, a second source region 92B, a second drain region 93B, a third source region 92C, and a third drain region 93C. The second conductivity type is the conductivity type that is the opposite of the conductivity type of the first, second, and third doped semiconductor material regions (22A, 22B, 22C) that are doped with dopants of the first conductivity type. Further, electrical dopants of the first conductivity type can be implanted into the first, second, and sixth device regions (200A, 200B, 200C) to form various source and drain regions, which can include, for example, a fourth source region 94A, a fourth drain region 95A, a fifth source region 94B, a fifth drain region 95B, a sixth source region 94C, and a sixth drain region 95C. The first conductivity type is the conductivity type that is the opposite of the conductivity type of the first, second, and sixth doped semiconductor material regions (24A, 24B, 24C) that are doped with dopants of the second conductivity type.

The formation of the various source regions and the various drain regions can be performed prior to, and/or after, formation of the various gate spacers (80A, 80B, 80C, 82A, 82B, 82C). The remaining portions of the first, second, and third intrinsic semiconductor material region (23A′, 23B′, 23C′) constitute a first semiconductor channel region 23A, a second semiconductor channel region 23B, and a third semiconductor channel region 23C, respectively. The remaining portions of the first, second, and sixth intrinsic semiconductor material region (25A′, 25B′, 25C′) constitute a fourth semiconductor channel region 25A, a fifth semiconductor channel region 25B, and a sixth semiconductor channel region 25C, respectively. Each of the semiconductor channel regions (23A, 23B, 23C, 25A, 25B, 25C) can include an intrinsic semiconductor material.

In some embodiments, some, or all, of the various source regions (92A, 92B, 92C, 94A, 94B, 94C) and/or some, or all, of the various drain regions (93A, 93B, 93C, 95A, 95B, 95C) can be formed by replacement of the semiconductor material in the corresponding intrinsic semiconductor material region(s) (23A′, 23B′, 23C′, 25A′, 25B′, 25C′) with a new semiconductor material having a different lattice constant. In this case, the new semiconductor material(s) is/are typically epitaxially aligned with the remaining single crystalline semiconductor material(s) of the corresponding intrinsic semiconductor material region(s) (23A′, 23B′, 23C′, 25A′, 25B′, 25C′), and apply/applies a compressive stress or a tensile stress to the corresponding semiconductor channel region(s) (23A, 23B, 23C, 25A, 25B, 25C).

Optionally, metal semiconductor alloy portions (not shown) can be formed on the physically exposed top surface of the various source regions (92A, 92B, 92C, 94A, 94B, 94C) and the various drain regions (93A, 93B, 93C, 95A, 95B, 95C), for example, by deposition of a metal layer and an anneal that forms a metal semiconductor alloy (such as a metal silicide). Unreacted remaining portions of the metal semiconductor alloy can be removed, for example, by a wet etch.

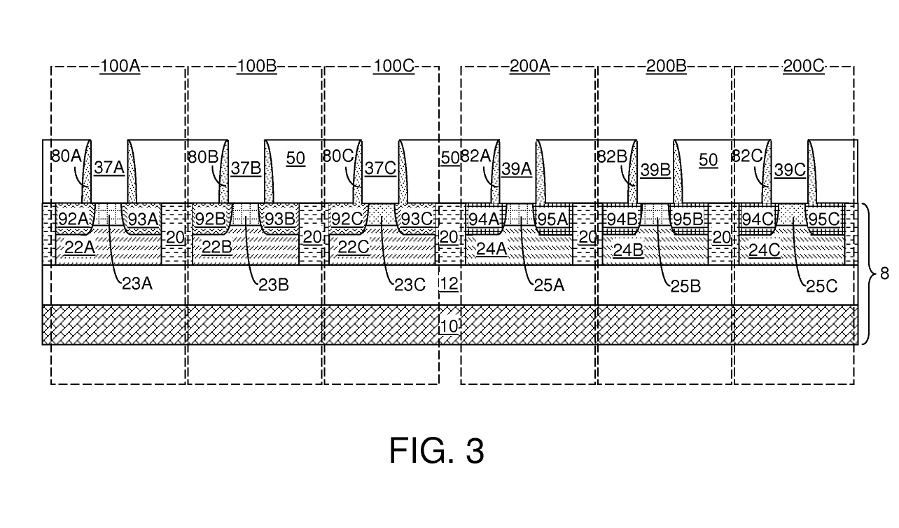

Referring to FIG. 3, a planarization dielectric layer 50 is deposited over the disposable gate structures (70, 72), the various gate spacers (80A, 80B, 80C, 82A, 82B, 82C), the various source regions (92A, 92B, 92C, 94A, 94B, 94C), and the various drain regions (93A, 93B, 93C, 95A, 95B, 95C). The planarization dielectric layer 50 includes a dielectric material, which can be a self-planarizing dielectric material such as a spin-on glass (SOG), or a non-planarizing dielectric material such as silicon oxide, silicon nitride, organosilicate glass, or combinations thereof. The planarization dielectric layer 50 is subsequently planarized, for example, by chemical mechanical planarization (CMP) such that top surfaces of the disposable gate structures (70, 72) become physically exposed. In one embodiment, the planarized top surface of the planarization dielectric layer 50 can be coplanar with the top surfaces of the disposable gate structures (70, 72).

Subsequently, the disposable gate stacks (70, 72) are removed selective to the planarization dielectric layer 50 and the various gate spacers (80A, 80B, 80C, 82A, 82B, 82C). The removal of the disposable gate stacks (70, 72) can be performed, for example, by an isotropic etch such as a wet etch, or by an anisotropic etch such as a reactive ion etch. Gate cavities are formed in spaces from which the disposable gate stacks (70, 72) are removed. The gate cavities can include, for example, a first gate cavity 37A that is formed in the first device region 100A, a second gate cavity 37B that is formed in the second device region 100B, a third gate cavity 37C that is formed in the third device region 100C, a fourth gate cavity 39A that is formed in the fourth device region 200A, a fifth gate cavity 39B that is formed in the fifth device region 200B, and a sixth gate cavity 39C that is formed in the sixth device region 200C. A semiconductor surface of an intrinsic semiconductor material is physically exposed at the bottom of each gate cavity (37A, 37B, 37C, 39A, 39B, 39C).

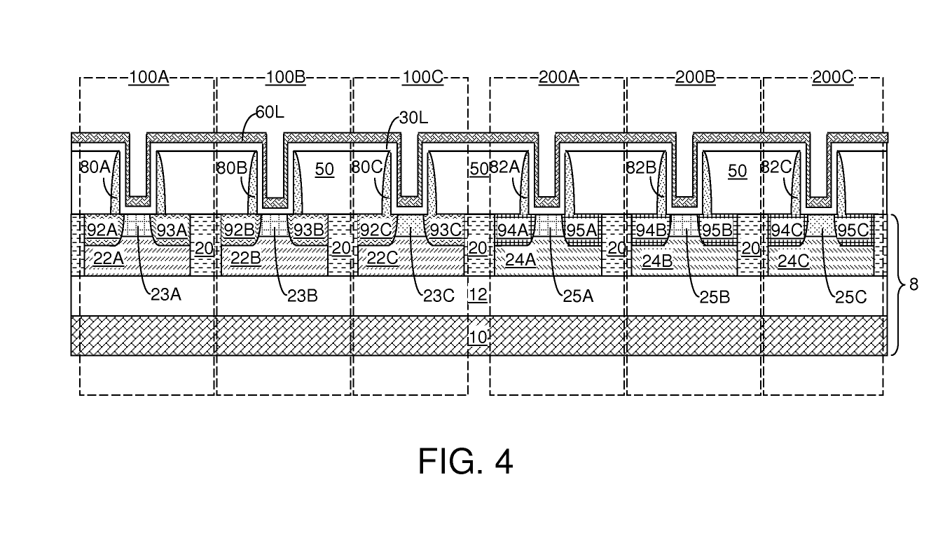

Referring to FIG. 4, a high dielectric constant (high-k) dielectric layer 30L is formed on the bottom surfaces and sidewall surfaces of the gate cavities (37A, 37B, 37C, 39A, 39B, 39C) and on the top surface of the planarization dielectric layer 50. The high-k dielectric layer 30L contacts inner sidewall surfaces of the gate spacers (80A, 80B, 80C, 82A, 82B, 82C). Optionally, a dielectric interface layer (not shown) may be formed directly on the top surfaces of the semiconductor channel regions (23A, 23B, 23C, 25A, 25B, 25C) before deposition of the high-k dielectric layer 30L. The dielectric interface layer may include a semiconductor oxide, a semiconductor oxynitride, or a semiconductor nitride. For example, the dielectric interface layer may be a “chemical oxide,” which is formed by treatment of top surfaces of the semiconductor channel regions (23A, 23B, 23C, 25A, 25B, 25C) with a chemical. The thickness of the dielectric interface layer, if present, may be from 0.1 nm to 0.8 nm, although lesser and greater thicknesses are also contemplated herein. Otherwise, the high-k dielectric material layer 30L may be formed directly on the semiconductor channel regions (23A, 23B, 23C, 25A, 25B, 25C).

The high dielectric constant (high-k) dielectric layer 30L can be formed on the semiconductor channel regions (23A, 23B, 23C, 25A, 25B, 25C) employing, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. The high-k dielectric layer 30L can include a high dielectric constant (high-k) dielectric material. As used herein, a “high-k dielectric material” refers to a dielectric material having a dielectric constant greater than the dielectric constant of silicon oxide, which is 3.9. The high-k dielectric layer 30L can have a dielectric constant greater than 4.0. In one embodiment, the high-k dielectric material can be a dielectric metal oxide having a dielectric constant that is greater than the dielectric constant of silicon nitride, which is 7.9. In one embodiment, the high-k dielectric layer 30L has a dielectric constant greater than 8.0. In one embodiment, the high-k dielectric layer 30L can consist essentially of a dielectric metal oxide having a dielectric constant greater than 8.0. The dielectric material of the high-k dielectric layer 30L is herein referred to as a first high-k dielectric material. In one embodiment, the first high-k dielectric material can include a material selected from hafnium oxide, zirconium oxide, tantalum oxide, titanium oxide, silicates of thereof, and alloys thereof. In one embodiment, the first high-k dielectric material can consist essentially of a material selected from hafnium oxide, zirconium oxide, tantalum oxide, titanium oxide, silicates of thereof, and alloys thereof. The thickness of the high-k dielectric layer 30L may be from 0.9 nm to 6 nm, and preferably from 1.2 nm to 3 nm. The high-k dielectric layer 30L may have an effective oxide thickness on the order of or less than 1 nm.

A diffusion barrier metallic nitride layer 60L is formed directly on the high-k dielectric layer 30L. The diffusion barrier metallic nitride layer 60L contains a metallic nitride material that functions as a diffusion barrier for metals. The diffusion barrier metallic nitride layer 60L may contain, for example, TiN, TaN, WN, or a combination thereof. The diffusion barrier metallic nitride layer 60L may be formed by chemical vapor deposition (CVD), physical vapor deposition (PVD), atomic layer deposition (ALD), vacuum evaporation, etc. The thickness of the diffusion barrier metallic nitride layer 60L may be from 3 nm to 30 nm, and typically from 5 nm 20 nm, although lesser and greater thicknesses are also contemplated herein.

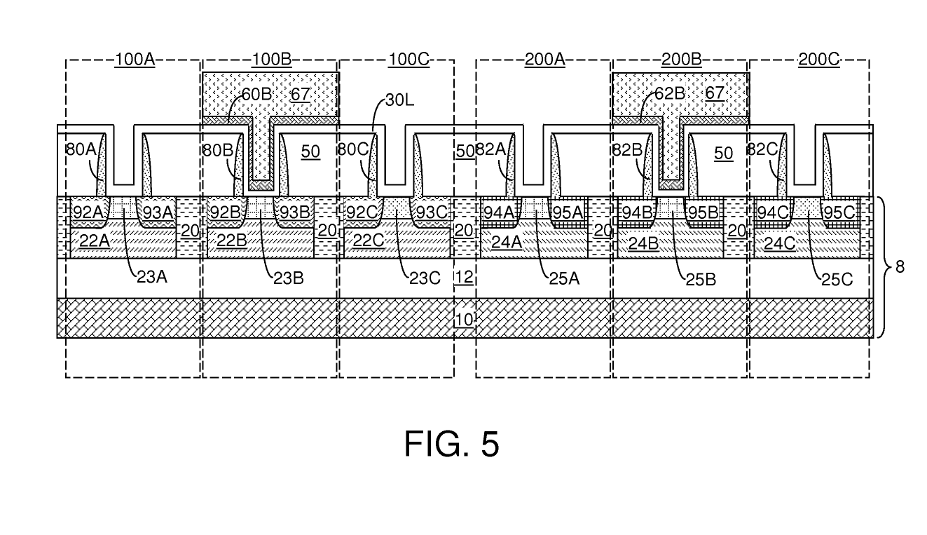

Referring to FIG. 5, a photoresist layer 67 is applied over the diffusion barrier metallic nitride layer 60L, and is lithographically patterned by lithographic exposure and development. The photoresist layer 67 is patterned to cover at least one gate cavity, while physically covering at least another gate cavity. The diffusion barrier metallic nitride layer 60L is then patterned by an etch process that employs the patterned photoresist layer 67 as an etch mask. Upon patterning of the diffusion barrier metallic nitride layer 60L, at least one portion of the high-k dielectric layer 30L is physically exposed while at least another portion of the high-k dielectric layer 30L is covered by a patterned portion of the diffusion barrier metallic nitride layer 30L.

In a non-limiting illustrative example, a first patterned portion of the diffusion barrier metallic nitride layer 30L can be present in the second device region 100B, and a second patterned portion of the diffusion barrier metallic nitride layer 30L can be present in the fifth device region 200B. The first patterned portion of the diffusion barrier metallic nitride layer 30L is herein referred to as a first-type diffusion barrier metallic nitride portion 60B, and the second patterned portion of the diffusion barrier metallic nitride layer 30L is herein referred to as a second-type diffusion barrier metallic nitride portion 62B. The first-type diffusion barrier metallic nitride portion 60B overlies the entirety of the gate cavity in the second device region 100B, and the second-type diffusion barrier metallic nitride portion 62B overlies the entirety of the gate cavity in the fifth device region 200B. While the present disclosure is described employing an embodiment in which patterned portions of the diffusion barrier metallic nitride layer 30L overlie gate cavities in the second device region 100B and the fifth device region 200B, embodiments are expressly contemplated herein in which patterned portions of the diffusion barrier metallic nitride layer 30L independently overlie any of the gate cavities in the various device regions (100A, 100B, 100C, 200A, 200B, 200C). The patterned photoresist layer 67 is subsequently removed, for example, by ashing.

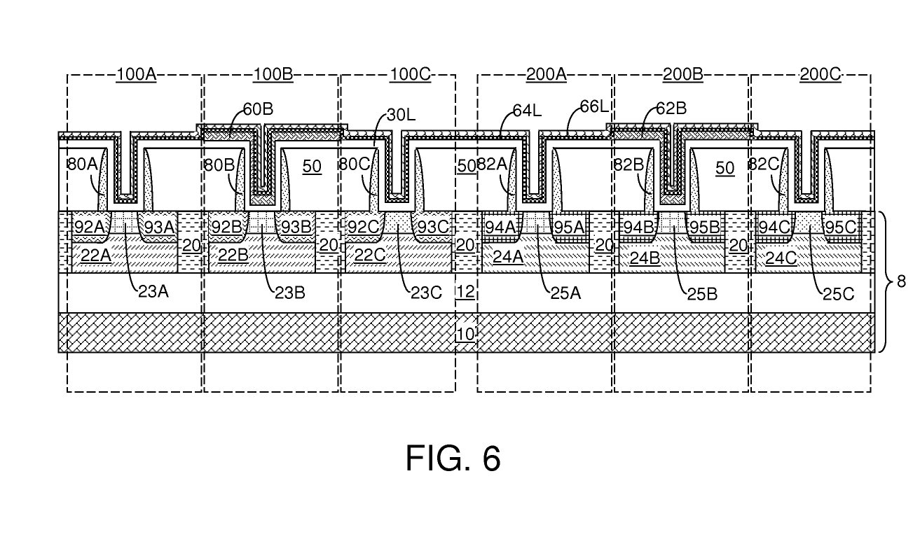

Referring to FIG. 6, a threshold voltage adjustment oxide layer 64L is deposited directly on the diffusion barrier metallic nitride portions (60B, 62B) and the high-k dielectric layer 30L. The threshold voltage adjustment oxide layer 64L includes a dielectric metal oxide having a dielectric constant that is greater than the dielectric constant of silicon oxide of 3.9. The threshold voltage adjustment oxide layer 64L can have dielectric constant greater than 4.0. In one embodiment, the threshold voltage adjustment oxide layer 64L has a dielectric constant greater than 8.0.

The dielectric material of the threshold voltage adjustment oxide layer 64L is herein referred to as a second high-k dielectric material. The second high-k dielectric material has a different composition than the first high-k dielectric material. In one embodiment, the second high-k dielectric material can include a material selected from an oxide of a Group IIA element, an oxide of a Group IIIB element, and alloys thereof. As such, the second high-k material of the threshold voltage adjustment oxide layer 64L alters the threshold voltage of a field effect transistor if the second high-k material contacts the channel of the field effect transistor or is placed in proximity with the channel at a distance less than about 2 nm (for example, spaced by a chemical oxide portion).

The threshold voltage adjustment oxide layer 64L can be formed employing, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. The thickness of the threshold voltage adjustment oxide layer 64L may be from 0.9 nm to 6 nm, and preferably from 1.2 nm to 3 nm. The threshold voltage adjustment oxide layer 64L may have an effective oxide thickness on the order of or less than 1 nm.

Optionally, a cap material layer 66L can be deposited over the threshold voltage adjustment oxide layer 64L. If a cap material layer 66L is employed, a portion of the cap material layer 66L is deposited directly on the threshold voltage adjustment oxide layer 64L. The cap material layer 66L includes at least one of a metallic material layer and a semiconductor material layer. In one embodiment, the cap material layer 66L includes a metallic nitride layer such as a TiN layer, a TaN layer, or a WN layer. In another embodiment, the cap material layer 66L includes an amorphous or polycrystalline semiconductor material layer including silicon, a silicon-germanium alloy, or a silicon-carbon alloy. In one embodiment, the cap material layer 66L can include a vertical stack, from bottom to top, of a metallic nitride layer and an amorphous or polycrystalline semiconductor material layer. The cap material layer 66L can be deposited, for example, by physical vapor deposition (PVD), chemical vapor deposition (CVD), atomic layer deposition (ALD), or a combination thereof. The cap material layer 66L can have a thickness in a range from 2 nm to 100 nm, although lesser and greater thicknesses can also be employed.

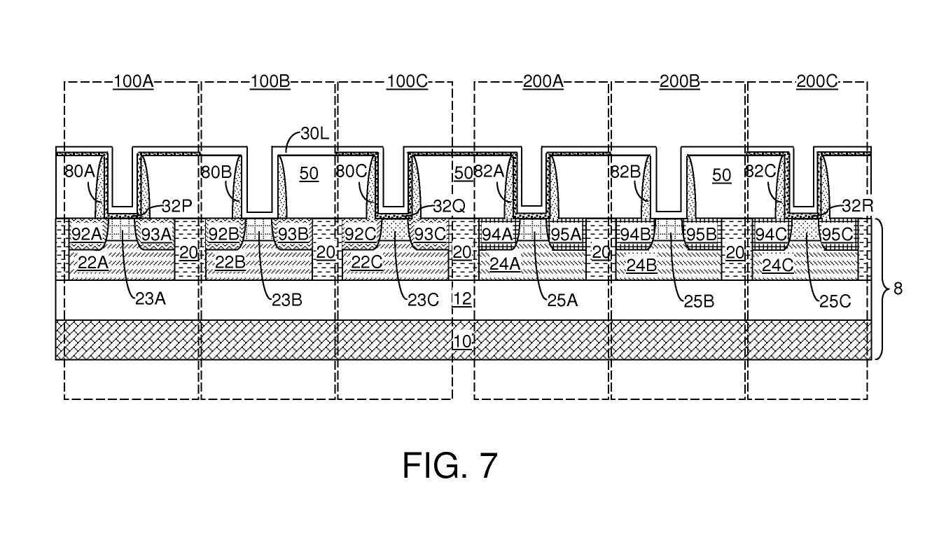

Referring to FIG. 7, the first exemplary semiconductor structure is annealed at an elevated temperature. The elevated temperature can be, for example, in a range from 900° C. to 1,100° C., although lower and higher temperatures can also be employed. The anneal induces diffusion of the second high-k dielectric material through the first high-k dielectric material. During the anneal, the diffusion barrier metallic nitride portions (60B, 62B), i.e., the patterned diffusion barrier metallic nitride layer, blocks diffusion of the second high-k dielectric material therethrough. The first high-k dielectric material diffuses through the second high-k dielectric material during the anneal, and accumulates at the interface with the semiconductor channel regions (23A, 23C, 25A, 25C), the gate spacers (80A, 80C, 82A, 82C), and the top surface of the planarization dielectric layer 50 that are present within the device regions (100A, 100C, 200A, 200C) in which the patterned diffusion barrier metallic nitride layer does not block the diffusion of the first high-k dielectric material. Thus, each threshold voltage adjustment oxide portion (32P, 32Q, 32R) is formed in (a) device region(s) in which the patterned diffusion barrier metallic nitride layer does not block the diffusion of the first high-k dielectric material. The threshold voltage adjustment oxide portions (32P, 32Q, 32R) are formed directly on at least one of the plurality of semiconductor material regions, and specifically, directly on the semiconductor channel regions (23A, 23C, 25A, 25C). In one embodiment, the concentration of the second high-k dielectric material can be the greatest at the interface with underlying semiconductor channel regions (23A, 23C, 25A, 25C).

The optional cap material layer 66L, the remaining portions of the threshold voltage adjustment oxide layer 64L overlying the diffusion barrier metallic nitride portions (60B, 62B), and the diffusion barrier metallic nitride portions (60B, 62B) are subsequently removed selective to the high-k dielectric layer 30L, i.e., without removing the high-k dielectric layer 30L. The selective removal of the optional cap material layer 66L, the remaining portions of the threshold voltage adjustment oxide layer 64L, and the diffusion barrier metallic nitride portions (60B, 62B) can be effected, for example, by a wet etch. In one embodiment, remaining portions of the threshold voltage adjustment oxide layer 64L after diffusion of the second high-k dielectric material through the high-k dielectric layer 30L can be removed selective to the first high-k dielectric material of the high-k dielectric layer, for example, by a wet etch.

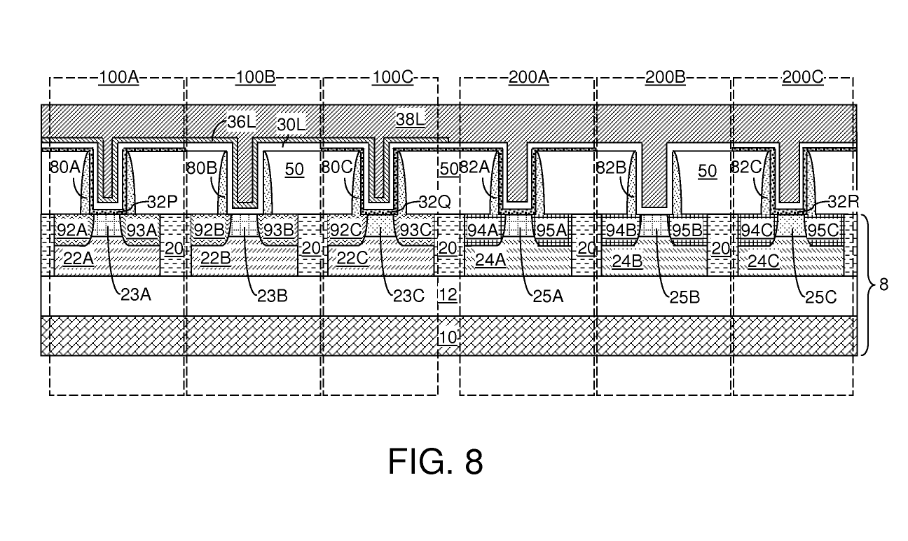

Referring to FIG. 8, at least one conductive material layer is deposited within the various gate trenches. In one embodiment, the at least one conductive material layer can include at least one work function material layer. In an illustrative example, a first work function material layer 36L can be deposited on the high-k dielectric layer 30L. The material of the first work function material layer 36L has a first work function, and can be selected from any work function material known in the art. The first work function material layer 36L can include an elemental only, or can include a metallic compound, which includes a metal and a non-metal element. The metallic compound is selected to optimize the performance of field effect transistor to be subsequently formed in the device regions in which first-type semiconductor channel regions (23A, 23B, 23C) are present. The metallic compound can be selected from tantalum carbide, metallic nitrides, and a hafnium-silicon alloy. Exemplary metallic nitrides include titanium nitride, tantalum nitride, tungsten nitride, and combinations and alloys thereof.

The first work function material layer 36L can be formed, for example, by physical vapor deposition, chemical vapor deposition, or atomic layer deposition (ALD). The thickness of the first work function material layer 36L is typically set at a value from 1 nm to 30 nm, and more typically, from 2 nm to 10 nm, although lesser and greater thicknesses can also be employed.

A photoresist layer (not shown) is applied and lithographic patterned so that the photoresist layer covers the area over the device regions in which first-type semiconductor channel regions (23A, 23B, 23C) are present, while the top surface of the first work function material layer 36L is exposed over the device regions in which second-type semiconductor channel regions (25A, 25B, 25C) are present. The pattern in the photoresist layer is transferred into the first work function material layer 36L by an etch. The portion of the first work function material layer 36L in the device regions in which second-type semiconductor channel regions (25A, 25B, 25C) are present is removed employing the photoresist layer as an etch mask. The photoresist layer is removed, for example, by ashing or wet etching. After the patterning of the first work function material layer 36L, a remaining portion of the first work function material layer 36L is present in the device regions in which first-type semiconductor channel regions (23A, 23B, 23C) are present. The photoresist layer is subsequently removed, for example, by ashing.

A second work function material layer 38L can be subsequently deposited. The second work function material layer 38L includes a second metal having a second work function, which can be different from the first work function. The material of the second work function material layer 38L can be selected from any work function material known in the art. The material of the second work function material layer 38L is selected to optimize the performance of the field effect transistor to be subsequently formed in the device regions in which second-type semiconductor channel regions (25A, 25B, 25C) are present.

The second work function material layer 38L can be formed, for example, by physical vapor deposition, chemical vapor deposition, or atomic layer deposition (ALD). The thickness of the second work function material layer 38L is typically set at a value from 2 nm to 100 nm, and more typically, from 3 nm to 10 nm, although lesser and greater thicknesses can also be employed.

In one embodiment, the first work function material layer 36L can include a work function material optimized for forming p-type field effect transistors and the second work function material layer 38L can include another work function material optimized for forming n-type field effect transistors. Alternatively, the first work function material layer 36L can include a work function material optimized for forming n-type field effect transistors and the second work function material layer 38L can include another work function material optimized for forming p-type field effect transistors.

In one embodiment, an additional conductive material layer (not shown) can be deposited on the second work function material layer 38L. The additional conductive material layer can include, for example, a doped semiconductor material layer and/or a metallic material layer.

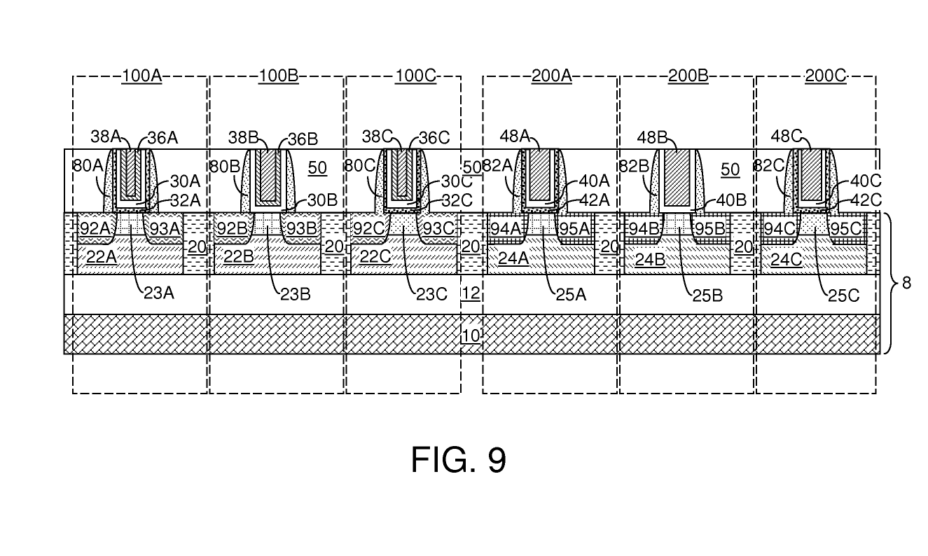

Referring to FIG. 9, gate stacks are formed by patterning the at least one conductive material layer (36L, 38L), the high-k dielectric layer 30L, and the at least one threshold voltage adjustment oxide portion (60B, 62B) by a planarization process. The planarization process can be a chemical mechanical planarization (CMP) process employing the planarization dielectric layer 50 as a stopping layer. In this case, the work function material layers (36L, 38L), the high-k dielectric layer 30L, and the at least one threshold voltage adjustment oxide portion (60B, 62B) from above the top surface of a planarization dielectric layer 50 by chemical mechanical planarization.

Remaining portions of the high-k dielectric layer 30L can include a first high-k dielectric layer 30A in the first device region 100A, a second high-k dielectric layer 30B in the second device region 100B, a third high-k dielectric layer 30C in the third device region 100C, a fourth high-k dielectric layer 40A in the fourth device region 200A, a fifth high-k dielectric layer 40B in the fifth device region 200B, and a sixth high-k dielectric layer 40C in the sixth device region 200C. Remaining portions of the threshold voltage adjustment oxide portion (32P, 32Q, 32R) can include a first threshold voltage adjustment oxide portion 32A in the first device region 100A, a second threshold voltage adjustment oxide portion 32C in the third device region 100C, a fourth threshold voltage adjustment oxide portion 42A in the fourth device region 200A, and a fifth threshold voltage adjustment oxide portion 42C in the sixth device region 200C. Remaining portions of the first work function material layer 36L can include a first first-work-function-material portion 36A, a second first-work-function-material portion 36B, and a third first-work-function-material portion 36C. Remaining portions of the second work function material layer 38L can include a first second-work-function-material portion 38A, a second second-work-function-material portion 38B, a third second-work-function-material portion 38C, a fourth second-work-function-material portion 48A, a fifth second-work-function-material portion 48B, and a sixth second-work-function-material portion 48C.

The first exemplary semiconductor structure can include a first field effect transistor including a first gate stack. The first gate stack can include, from bottom to top, a first high dielectric constant (high-k) dielectric portion (such as the second dielectric portion 30B) including the first high-k dielectric material having a dielectric constant greater than 4.0 and overlying a first semiconductor channel region (such as the second semiconductor channel region 23B), and a first gate electrode (such as the stack of the second first-work-function-material portion 36B and the second second-work-function-material portion 38B) contacting the first high-k dielectric portion.

The first exemplary semiconductor structure can further include a second field effect transistor including a second gate stack. The second gate stack includes, from bottom to top, a threshold voltage adjustment oxide portion (such as the first threshold voltage adjustment oxide portion 32A) including the second high-k dielectric material having a second high-k dielectric constant greater than 4.0 and different from the first high-k dielectric material and overlying a second semiconductor channel region (such as the first semiconductor channel region 23A), a second high-k dielectric portion (such as the first high-k dielectric layer 30A) including the first high-k dielectric material, and a second gate electrode (such as the stack of the first first-work-function-material portion 36A and the first second-work-function-material portion 38A) contacting the second high-k dielectric portion.

The first exemplary semiconductor structure can further include at least one second-type field effect transistor including another gate stack. The gate stack can include at least, from bottom to top, a high-k dielectric portion including the first high-k dielectric material and a gate electrode contacting the third high-k dielectric portion.

The at least one second-type field effect transistor can include a fourth field effect transistor including a third gate stack. The third gate stack can includes at least, from bottom to top, a threshold voltage adjustment oxide portion (such as the fourth threshold voltage adjustment oxide portion 42A) including the second high-k dielectric material and overlying a third semiconductor channel region (such as the fourth semiconductor channel region 25A), a third high-k dielectric portion (such as the fourth high-k dielectric layer 40A) including the first high-k dielectric material, and a third gate electrode (such as the fourth second-work-function-material portion 48A) contacting the third high-k dielectric portion.

The at least one second-type field effect transistor can include a fifth field effect transistor including a fourth gate stack. The fourth gate stack can include, from bottom to top, a threshold voltage adjustment oxide portion (such as the sixth threshold voltage adjustment oxide portion 42C) including the second high-k dielectric material and overlying a fourth semiconductor channel region (such as the sixth semiconductor channel region 25C), a fourth high-k dielectric portion (such as the sixth semiconductor channel region 25C) including the first high-k dielectric material, and a fourth gate electrode (such as the sixth second-work-function-material portion 48C) contacting the fourth high-k dielectric portion. The third semiconductor channel region and the fourth semiconductor channel region can be single crystalline intrinsic semiconductor material portions including different semiconductor materials.

Alternatively or additionally, the at least one second field effect transistor can include another field effect transistor including a gate stack. The gate stack can include a high-k dielectric portion (such as the fifth high-k dielectric layer 40B) including the first high-k dielectric material and overlying a semiconductor channel region (such as the fifth semiconductor channel region 25B) and a gate electrode (such as the fifth second-work-function-material portion 48C) contacting the high-k dielectric portion.

In one embodiment, the atomic concentration of the second high-k dielectric material can decrease with distance from the interface between the underlying semiconductor channel region (23A, 23C, 25A, 25C) and the underlying threshold voltage adjustment oxide portion (32A, 32C, 42A, 42C) within a high-k dielectric layer (30A, 30C, 40A, 40C) including the first high-k dielectric material and the diffused second high-k dielectric material. A predominant portion, i.e., more than 50% in atomic concentration, of each high-k dielectric layer (30A, 30C, 40A, 40C) can be the first high-k dielectric material, and the balance can be the second high-k dielectric material.

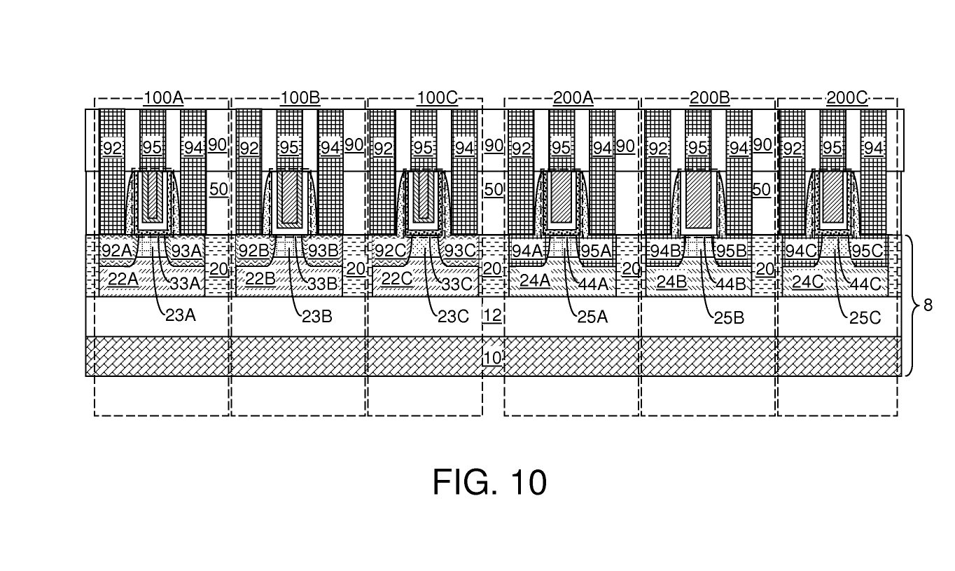

Referring to FIG. 10, a contact level dielectric layer 90 can be deposited over the planarization dielectric layer 50, for example, by chemical vapor deposition (CVD) or spin-coating. The contact level dielectric layer 90 includes a dielectric material such as silicon oxide, silicon nitride, and/or organosilicate glass. Various contact via structures can be formed through the contact level dielectric layer 90 and the planarization dielectric layer 50. The various contact via structures can include, for example, source-side contact via structures 92, drain-side contact via structures 94, and gate-side contact via structures 95. A first gate stack 33A is present in the first device region 100A, a second gate stack 33B is present in the second device region 100B, a third gate stack 33C is present in the third device region 100C, a fourth gate stack 33A is present in the fourth device region 200A, a fifth gate stack 33B is present in the fifth device region 200B, and a sixth gate stack 33C is present in the sixth device region 200C.

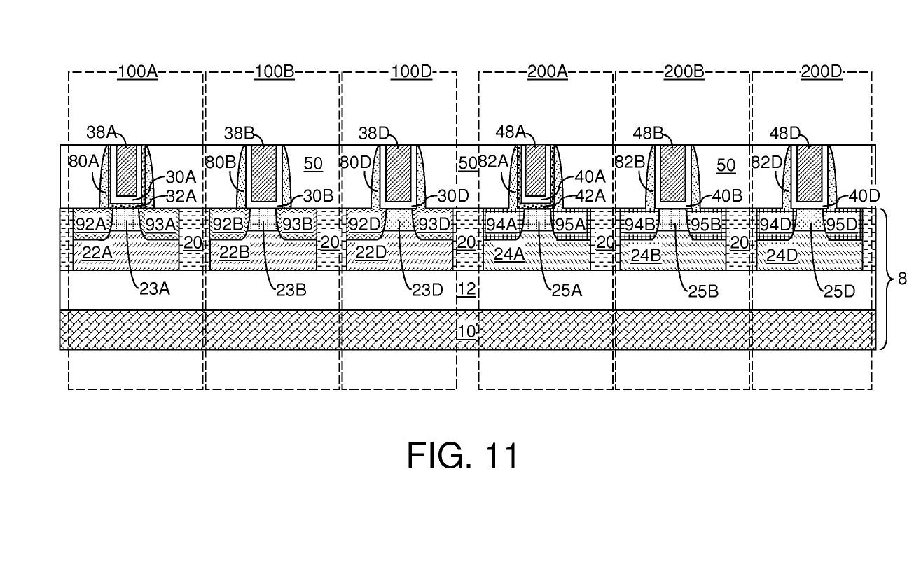

Referring to FIG. 11, a variation of the first exemplary semiconductor structure can be derived from the first exemplary semiconductor structure by adding a fourth first-type device region 100D and/or a fourth second-type device region 200D and by performing the processing steps of FIGS. 1-9, provided that a single work function material layer such as a second work function material layer 38L is employed in lieu of the combination of the first work function material layer 36L and the second work function material layer 38L. Alternatively, the fourth first-type device region 100D can substitute any of the first-type device regions (100A, 100B, 100C), and/or the fourth second-type device region 200D can substitute any of the second-type device regions (200A, 200B, 200C), provided that a single work function material layer such as a second work function material layer 38L is employed in lieu of the combination of the first work function material layer 36L and the second work function material layer 38L.

The fourth first-type device region 100D can include a fourth first-type doped semiconductor material region 22D having a same composition as a third doped semiconductor material region 22C (See FIG. 9), and a fourth first-type semiconductor channel region 23C having a same composition as a third semiconductor channel region 23C (See FIG. 9). The fourth first-type device region 100D can further include a fourth first-type source region 92D having a same composition as a third source region 92C (See FIG. 9), and a fourth first-type drain region 93D having a same composition as a third drain region 93C (See FIG. 9). The fourth-type device region 100D can include a fourth first-type gate spacer 80D having a same composition and thickness as a third gate spacer 80C (See FIG. 9). The fourth first-type device region 100D can include a fourth first-type high-k gate dielectric layer 30D having a same composition as a second high-k gate dielectric layer 30B, and a fourth first-type work-function-material portion 38D having a same composition as a second work-function-material portion 38B.

The fourth second-type device region 200D can include a fourth second-type doped semiconductor material region 24D having a same composition as a sixth doped semiconductor material region 24C (See FIG. 9), and a fourth second-type semiconductor channel region 25C having a same composition as a sixth semiconductor channel region 25C (See FIG. 9). The fourth second-type device region 200D can further include a fourth second-type source region 94D having a same composition as a sixth source region 94C (See FIG. 9), and a fourth second-type drain region 95D having a same composition as a sixth drain region 95C (See FIG. 9). The fourth-type device region 200D can include a fourth second-type gate spacer 82D having a same composition and thickness as a sixth gate spacer 82C (See FIG. 9). The fourth second-type device region 200D can include a fourth second-type high-k gate dielectric layer 40D having a same composition as a fifth high-k gate dielectric layer 40B, and a fourth second-type work-function-material portion 48D having a same composition as a fifth work-function-material portion 48B. The processing steps of FIG. 10 can be subsequently performed.

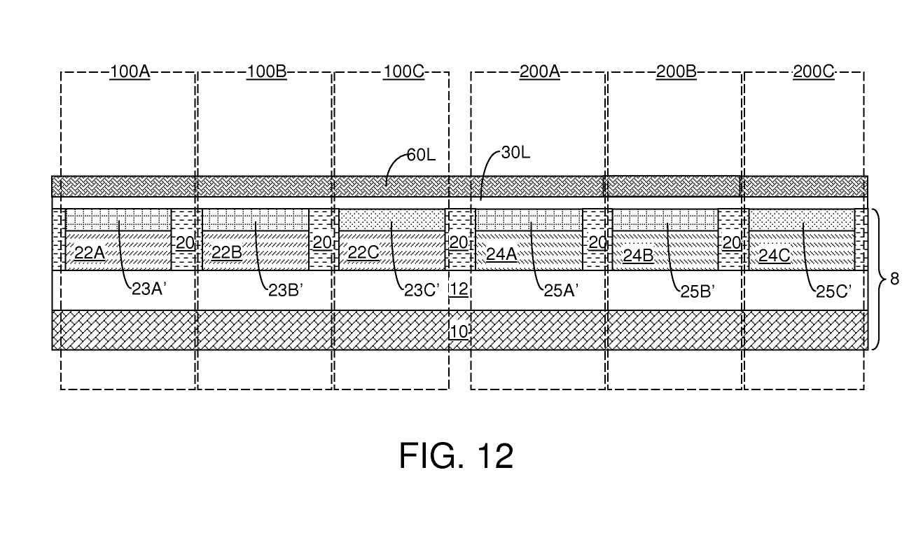

Referring to FIG. 12, a second exemplary semiconductor structure according to the second embodiment of the present disclosure can be derived from the first exemplary semiconductor structure of FIG. 1 by performing the processing steps of FIG. 4 without performing the processing steps of FIGS. 2 and 3. In the second embodiment, the high-k dielectric layer 30L and the diffusion barrier metallic nitride layer 60L can be formed as blanket layers having the same thickness throughout.

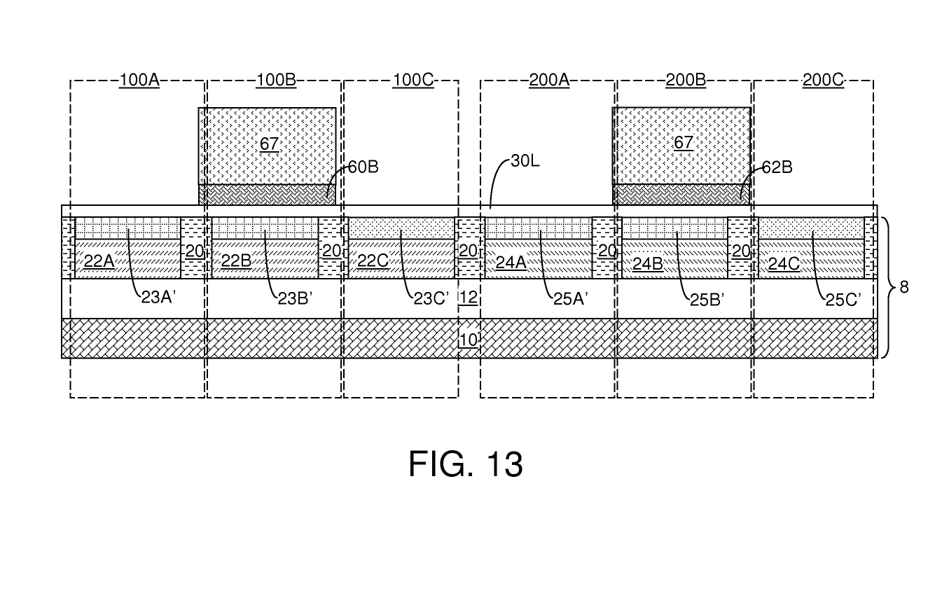

Referring to FIG. 13, the diffusion barrier metallic nitride layer 60L is patterned employing the processing steps of the first embodiment corresponding to FIG. 5.

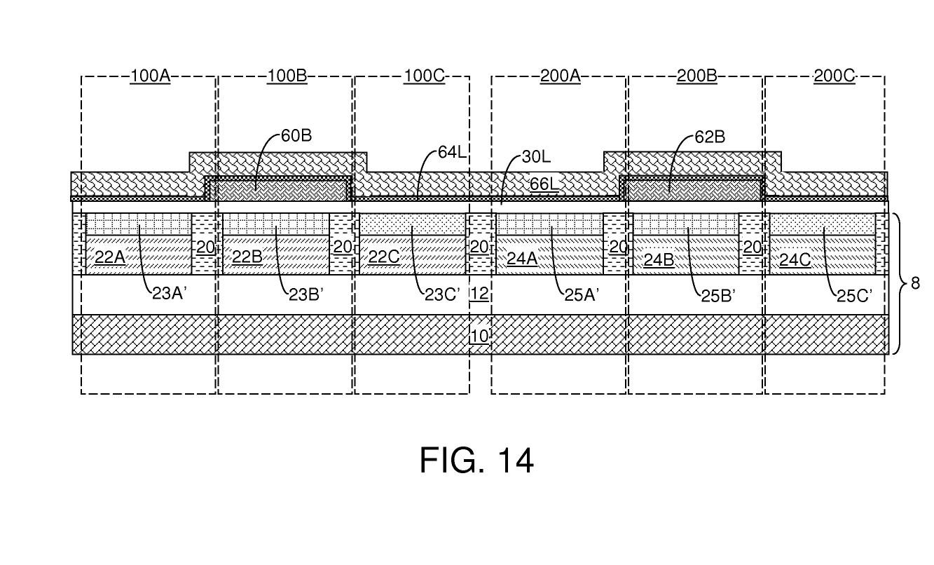

Referring to FIG. 14, a threshold voltage adjustment oxide layer 64L and an optional cap material layer 66L are deposited employing the processing steps of the first embodiment corresponding to FIG. 6.

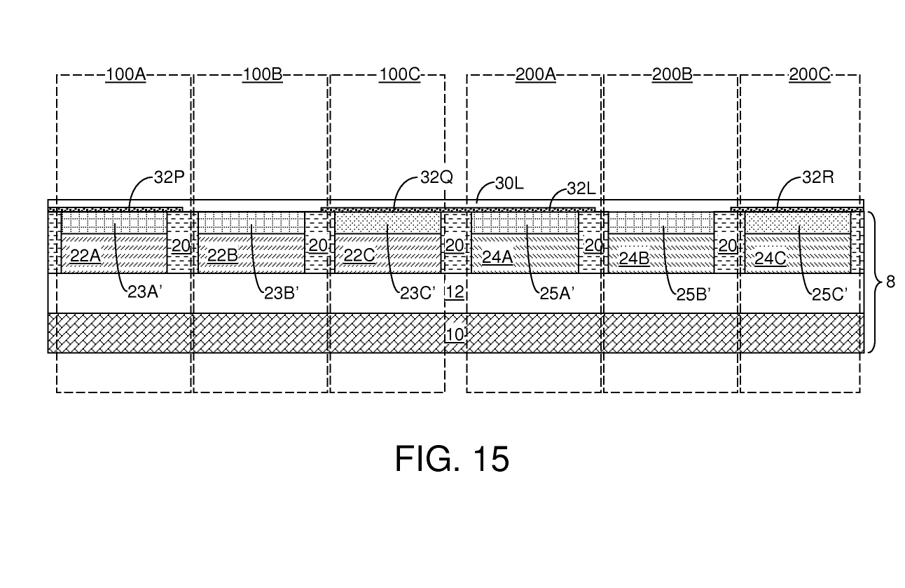

Referring to FIG. 15, an anneal is performed to form threshold voltage adjust oxide portions (32P, 32Q, 32R) between intrinsic semiconductor material regions (23A′, 23C′, 25A′, 25C′) and the high-k gate dielectric layer 30L employing the processing steps of the first embodiment corresponding to FIG. 7.

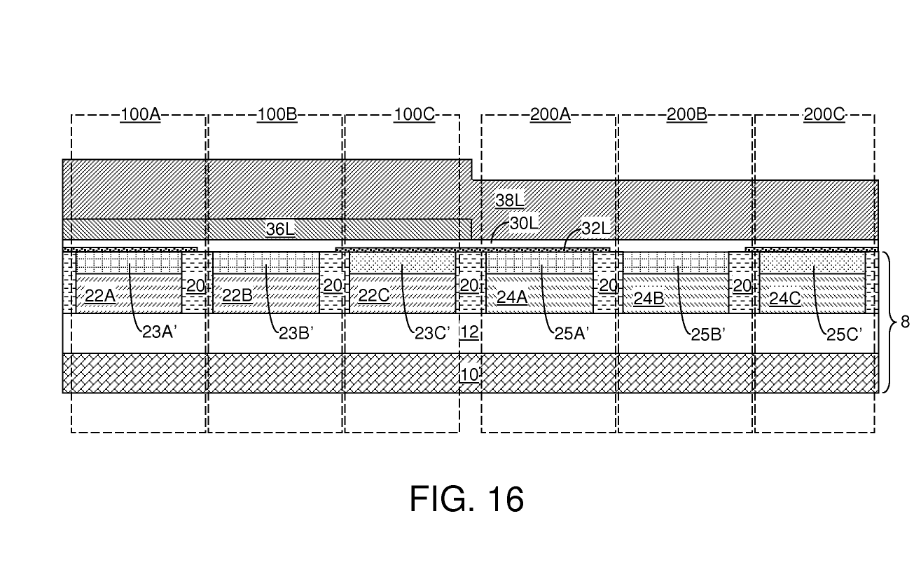

Referring to FIG. 16, at least one conductive material layer (36L, 38L) is deposited employing the processing steps of the first embodiment corresponding to FIG. 8.

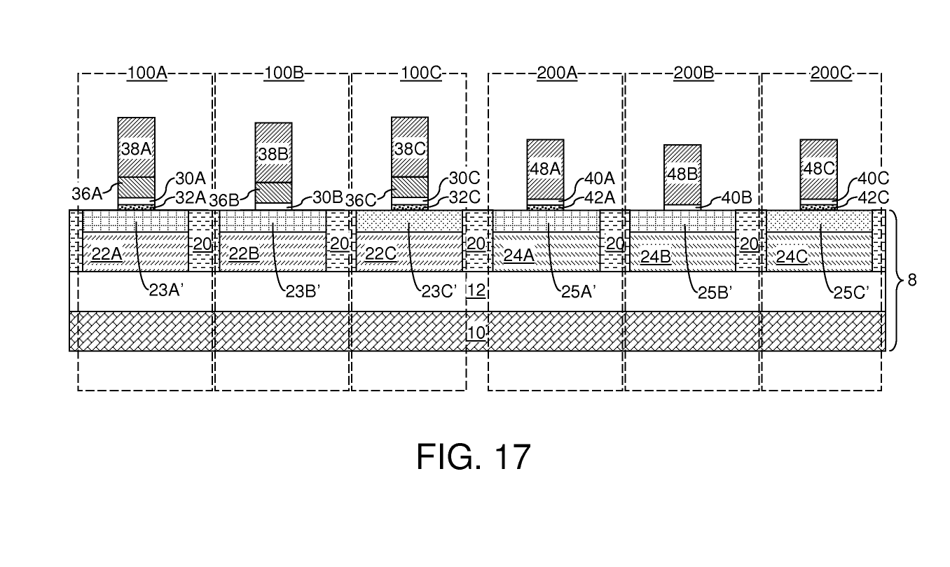

Referring to FIG. 17, various gate stacks are patterned by a combination of lithographic methods and at least one anisotropic etch. For example, a photoresist layer (not shown) can be applied over the at least one conductive material layer (36L, 38L) and patterned by lithographic exposure and development, and the pattern in the photoresist layer can be transferred through the at least one conductive material layer (36L, 38L), the high-k dielectric layer 30L, and the threshold voltage adjust oxide portions (32P, 32Q, 32R).

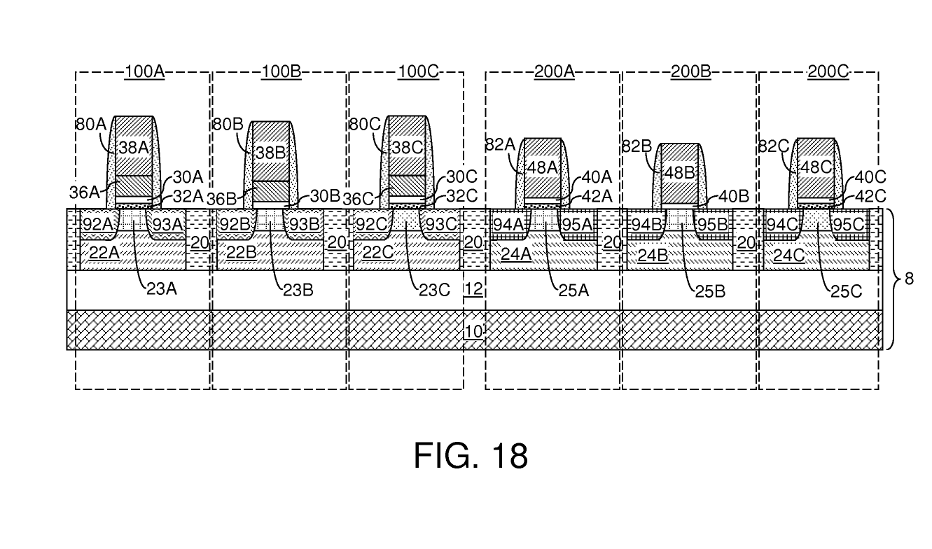

Referring to FIG. 18, gate spacers (80A, 30B, 30C, 82A, 82B, 82C), source regions (92A, 92B, 92C, 94A, 94B, 94C), and drain regions (93A, 93B, 93C, 95A, 95B, 95C) are formed employing the processing steps of the first embodiment corresponding to FIG. 2.

Remaining portions of the high-k dielectric layer 30L can include a first high-k dielectric layer 30A in the first device region 100A, a second high-k dielectric layer 30B in the second device region 100B, a third high-k dielectric layer 30C in the third device region 100C, a fourth high-k dielectric layer 40A in the fourth device region 200A, a fifth high-k dielectric layer 40B in the fifth device region 200B, and a sixth high-k dielectric layer 40C in the sixth device region 200C. Remaining portions of the threshold voltage adjustment oxide portion (32P, 32Q, 32R) can include a first threshold voltage adjustment oxide portion 32A in the first device region 100A, a second threshold voltage adjustment oxide portion 32C in the third device region 100C, a fourth threshold voltage adjustment oxide portion 42A in the fourth device region 200A, and a fifth threshold voltage adjustment oxide portion 42C in the sixth device region 200C. Remaining portions of the first work function material layer 36L can include a first first-work-function-material portion 36A, a second first-work-function-material portion 36B, and a third first-work-function-material portion 36C. Remaining portions of the second work function material layer 38L can include a first second-work-function-material portion 38A, a second second-work-function-material portion 38B, a third second-work-function-material portion 38C, a fourth second-work-function-material portion 48A, a fifth second-work-function-material portion 48B, and a sixth second-work-function-material portion 48C.

The second exemplary semiconductor structure can include a first field effect transistor including a first gate stack. The first gate stack can include, from bottom to top, a first high dielectric constant (high-k) dielectric portion (such as the second dielectric portion 30B) including the first high-k dielectric material having a dielectric constant greater than 4.0 and contacting a first semiconductor channel region (such as the second semiconductor channel region 23B), and a first gate electrode (such as the stack of the second first-work-function-material portion 36B and the second second-work-function-material portion 38B) contacting the first high-k dielectric portion.

The second exemplary semiconductor structure can further include a second field effect transistor including a second gate stack. The second gate stack includes, from bottom to top, a threshold voltage adjustment oxide portion (such as the first threshold voltage adjustment oxide portion 32A) including the second high-k dielectric material having a second high-k dielectric constant greater than 4.0 and different from the first high-k dielectric material and overlying a second semiconductor channel region (such as the first semiconductor channel region 23A), a second high-k dielectric portion (such as the first high-k dielectric layer 30A) including the first high-k dielectric material, and a second gate electrode (such as the stack of the first first-work-function-material portion 36A and the first second-work-function-material portion 38A) contacting the second high-k dielectric portion.

The second exemplary semiconductor structure can further include at least one second-type field effect transistor including another gate stack. The gate stack can include at least, from bottom to top, a high-k dielectric portion including the first high-k dielectric material and a gate electrode contacting the third high-k dielectric portion.

The at least one second-type field effect transistor can include a fourth field effect transistor including a third gate stack. The third gate stack can includes at least, from bottom to top, a threshold voltage adjustment oxide portion (such as the fourth threshold voltage adjustment oxide portion 42A) including the second high-k dielectric material and overlying a third semiconductor channel region (such as the fourth semiconductor channel region 25A), a third high-k dielectric portion (such as the fourth high-k dielectric layer 40A) including the first high-k dielectric material, and a third gate electrode (such as the fourth second-work-function-material portion 48A) contacting the third high-k dielectric portion.

The at least one second-type field effect transistor can include a fifth field effect transistor including a fourth gate stack. The fourth gate stack can include, from bottom to top, a threshold voltage adjustment oxide portion (such as the sixth threshold voltage adjustment oxide portion 42C) including the second high-k dielectric material and overlying a fourth semiconductor channel region (such as the sixth semiconductor channel region 25C), a fourth high-k dielectric portion (such as the sixth semiconductor channel region 25C) including the first high-k dielectric material, and a fourth gate electrode (such as the sixth second-work-function-material portion 48C) contacting the fourth high-k dielectric portion. The third semiconductor channel region and the fourth semiconductor channel portions can be single crystalline intrinsic semiconductor material portions including different semiconductor materials.

Alternatively or additionally, the at least one second field effect transistor can include another field effect transistor including a gate stack. The gate stack can include a high-k dielectric portion (such as the fifth high-k dielectric layer 40B) including the first high-k dielectric material and overlying a semiconductor channel region (such as the fifth semiconductor channel region 25B) and a gate electrode (such as the fifth second-work-function-material portion 48C) contacting the high-k dielectric portion.

In one embodiment, the atomic concentration of the second high-k dielectric material can decrease with distance from the interface between the underlying semiconductor channel region (23A, 23C, 25A, 25C) and the underlying threshold voltage adjustment oxide portion (32A, 32C, 42A, 42C) within a high-k dielectric layer (30A, 30C, 40A, 40C) including the first high-k dielectric material and the diffused second high-k dielectric material.

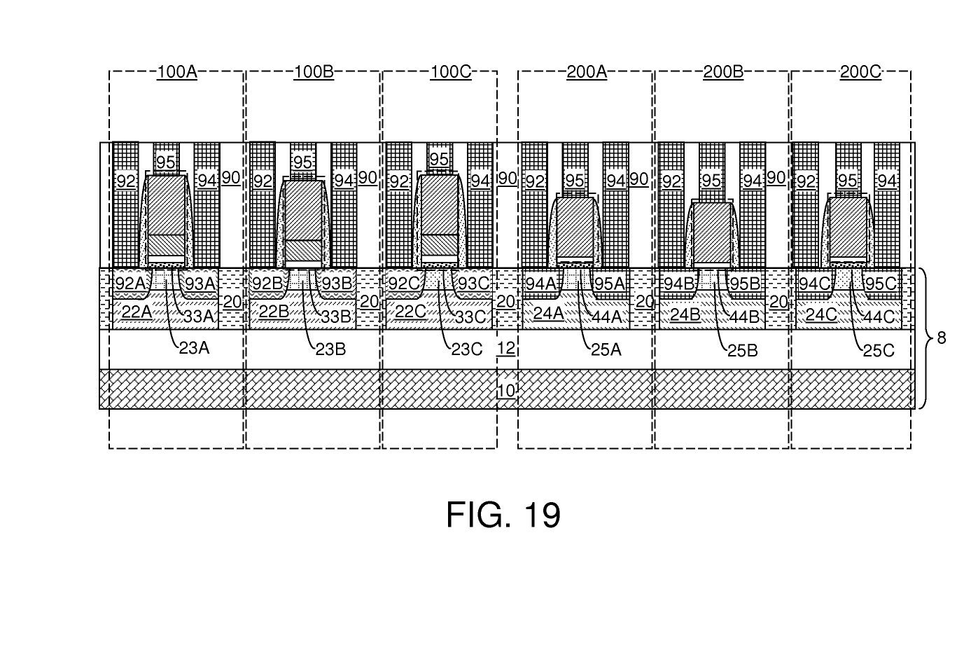

Referring to FIG. 19, a contact level dielectric layer 90 can be deposited over gate stacks, for example, by chemical vapor deposition (CVD) or spin-coating. The contact level dielectric layer 90 includes a dielectric material such as silicon oxide, silicon nitride, and/or organosilicate glass. Various contact via structures can be formed through the contact level dielectric layer 90. The various contact via structures can include, for example, source-side contact via structures 92, drain-side contact via structures 94, and gate-side contact via structures 95.

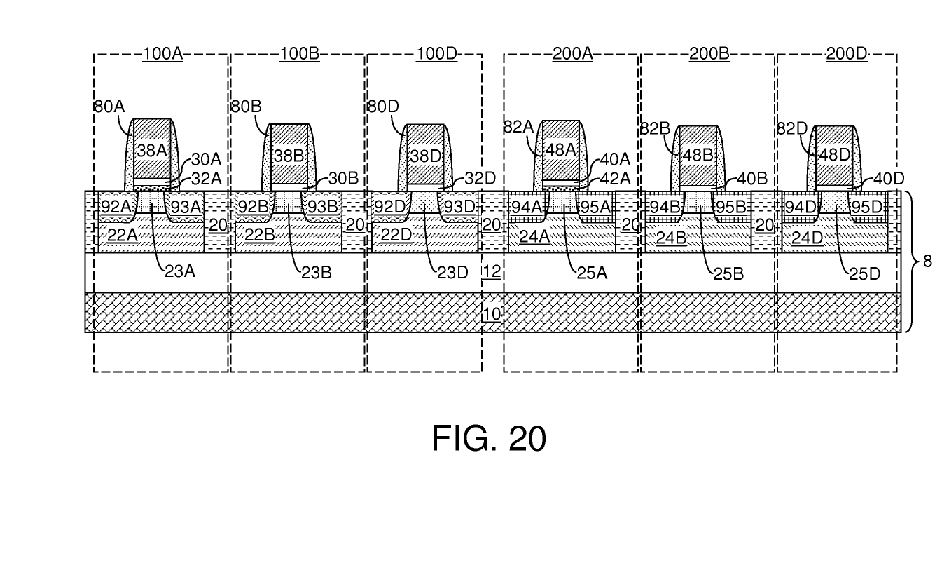

Referring to FIG. 20, a variation of the second exemplary semiconductor structure can be derived from the second exemplary semiconductor structure by adding a fourth first-type device region 100D and/or a fourth second-type device region 200D and by performing the processing steps of FIGS. 12-18, provided that a single work function material layer such as a second work function material layer 38L is employed in lieu of the combination of the first work function material layer 36L and the second work function material layer 38L. Alternatively, the fourth first-type device region 100D can substitute any of the first-type device regions (100A, 100B, 100C), and/or the fourth second-type device region 200D can substitute any of the second-type device regions (200A, 200B, 200C), provided that a single work function material layer such as a second work function material layer 38L is employed in lieu of the combination of the first work function material layer 36L and the second work function material layer 38L.

The fourth first-type device region 100D can include a fourth first-type doped semiconductor material region 22D having a same composition as a third doped semiconductor material region 22C (See FIG. 18), and a fourth first-type semiconductor channel region 23C having a same composition as a third semiconductor channel region 23C (See FIG. 18). The fourth first-type device region 100D can further include a fourth first-type source region 92D having a same composition as a third source region 92C (See FIG. 18), and a fourth first-type drain region 93D having a same composition as a third drain region 93C (See FIG. 18). The fourth-type device region 100D can include a fourth first-type gate spacer 80D having a same composition and thickness as a third gate spacer 80C (See FIG. 18). The fourth first-type device region 100D can include a fourth first-type high-k gate dielectric layer 30D having a same composition as a second high-k gate dielectric layer 30B, and a fourth first-type work-function-material portion 38D having a same composition as a second work-function-material portion 38B.

The fourth second-type device region 200D can include a fourth second-type doped semiconductor material region 24D having a same composition as a sixth doped semiconductor material region 24C (See FIG. 18), and a fourth second-type semiconductor channel region 25C having a same composition as a sixth semiconductor channel region 25C (See FIG. 18). The fourth second-type device region 200D can further include a fourth second-type source region 94D having a same composition as a sixth source region 94C (See FIG. 18), and a fourth second-type drain region 95D having a same composition as a sixth drain region 95C (See FIG. 18). The fourth-type device region 200D can include a fourth second-type gate spacer 82D having a same composition and thickness as a sixth gate spacer 82C (See FIG. 18). The fourth second-type device region 200D can include a fourth second-type high-k gate dielectric layer 40D having a same composition as a fifth high-k gate dielectric layer 40B, and a fourth second-type work-function-material portion 48D having a same composition as a fifth work-function-material portion 48B. The processing steps of FIG. 19 can be subsequently performed.

The methods of the various embodiments of the present disclosure enable formation of field effect transistors having different threshold voltages without employing a doped channel region. By eliminating the doping of the channel regions, i.e., by employing intrinsic semiconductor materials as the semiconductor materials for channel regions, variations in the threshold voltage of the field effect transistors due to stochastic variations in the dopant distribution can be eliminated. Thus, the field effect transistors of the present disclosure can provide a tighter distribution of threshold voltages for multiple types of field effect transistors of the same conductivity type, i.e., for each of p-type field effect transistors and n-type field effect transistors.

While the present disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the present disclosure is intended to encompass all such alternatives, modifications and variations which fall within the scope and spirit of the present disclosure and the following claims.

What is claimed is:

1. A semiconductor structure comprising:
a first field effect transistor including a first gate stack containing a first high dielectric constant (high-k) dielectric portion and a first gate electrode contacting said first high-k dielectric portion, said first high-k dielectric portion comprises a first high-k dielectric material and overlies a first semiconductor channel region;
a second field effect transistor including a second gate stack containing a threshold voltage adjustment oxide portion, a second high-k dielectric portion comprising said first high-k dielectric material, and a second gate electrode contacting said second high-k dielectric portion, wherein said threshold voltage adjustment oxide portion comprises a second high-k dielectric material different from said first high-k dielectric material and overlies a second semiconductor channel region; and
a third field effect transistor including a third gate stack containing at least a third high-k dielectric portion comprising said first high-k dielectric material and a third gate electrode contacting said third high-k dielectric portion, wherein said first and third field effect transistors are of complementary types.

2. The semiconductor structure of claim 1, wherein each of said first semiconductor channel region and said second semiconductor channel region are intrinsic semiconductor material portions.

3. The semiconductor structure of claim 2, further comprising:
a first doped semiconductor material region in contact with a bottom surface of said first semiconductor channel region; and
a second doped semiconductor material region in contact with a bottom surface of said second semiconductor channel region.

4. The semiconductor structure of claim 2, wherein a stack of said first doped semiconductor material portion and said first semiconductor channel region comprises a first semiconductor material throughout, and a stack of said second doped semiconductor material portion and said second semiconductor material channel region comprises a second semiconductor material throughout, and wherein each of said first semiconductor material and said second semiconductor material is independently selected from single crystalline silicon, a single crystalline silicon-germanium alloy, a single crystalline silicon-carbon alloy, and a single crystalline silicon-germanium-carbon alloy.

5. The semiconductor structure of claim 1, wherein said third high-k dielectric portion contacts a third semiconductor channel region.

6. The semiconductor structure of claim 5, further comprising a fourth field effect transistor including a fourth gate stack, wherein said fourth gate stack comprises, from bottom to top, another threshold voltage adjustment oxide portion comprising said another dielectric material and overlying a fourth semiconductor channel region, a fourth high-k dielectric portion comprising said first high-k dielectric material, and a fourth gate electrode contacting said fourth high-k dielectric portion.

7. The semiconductor structure of claim 1, wherein said third field effect transistor comprises a third gate stack, wherein said third gate stack includes at least, from bottom to top, another threshold voltage adjustment oxide portion comprising said another dielectric material and overlying a third semiconductor channel region, a third high-k dielectric portion comprising said first high-k dielectric material, and a third gate electrode contacting said third high-k dielectric portion.

8. The semiconductor structure of claim 7, further comprising a fourth field effect transistor including a fourth gate stack, wherein said fourth gate stack comprises, from bottom to top, yet another threshold voltage adjustment oxide portion comprising said another dielectric material and overlying a fourth semiconductor channel region, a fourth high-k dielectric portion comprising said first high-k dielectric material, and a fourth gate electrode contacting said fourth high-k dielectric portion, wherein said third semiconductor channel region and said fourth semiconductor channel portions are single crystalline intrinsic semiconductor material portions including different semiconductor materials.

9. The semiconductor structure of claim 1, wherein said first high-k dielectric material comprises a material selected from hafnium oxide, zirconium oxide, tantalum oxide, titanium oxide, silicates of thereof, and alloys thereof.

10. The semiconductor structure of claim 9, wherein said second high-k dielectric material comprises a material selected from an oxide of a Group IIA element, an oxide of a Group IIIB element, and alloys thereof.

11. A method of forming a semiconductor structure comprising:
forming a high dielectric constant (high-k) dielectric layer comprising a first high-k dielectric material on a plurality of semiconductor material regions in a semiconductor substrate;
forming and patterning a diffusion barrier metallic nitride layer, wherein at least one portion of said high-k dielectric layer is physically exposed while at least another portion of said high-k dielectric layer is covered by a patterned portion of said diffusion barrier metallic nitride layer;
forming a threshold voltage adjustment oxide layer comprising a second high-k dielectric material over said high-k dielectric layer and said patterned diffusion barrier metallic nitride layer;
inducing diffusion of said second high-k dielectric material through said first high-k dielectric material by an anneal, wherein said patterned diffusion barrier metallic nitride layer blocks diffusion of said second high-k dielectric material therethrough and at least one threshold voltage adjustment oxide portion is formed directly on at least one of said plurality of semiconductor material regions;
removing said patterned diffusion barrier metallic nitride layer;
forming at least one conductive material layer on said high-k dielectric layer; and
forming gate stacks by patterning said at least one conductive material layer, said high-k dielectric layer, and said at least one threshold voltage adjustment oxide portion.

12. The method of claim 11, further comprising:
forming a cap material layer directly on said patterned diffusion barrier metallic nitride layer prior to said anneal; and
removing said cap material layer after said anneal.

13. The method of claim 12, wherein a portion of said cap material layer is deposited directly on said threshold voltage adjustment oxide layer.

14. The method of claim 12, wherein said cap material layer comprises at least one of a metallic material layer and a semiconductor material layer.

15. The method of claim 11, further comprising:
forming a first field effect transistor including a first gate stack, wherein said first gate stack includes, from bottom to top, a first high dielectric constant (high-k) dielectric portion comprising said first high-k dielectric material and overlying a first semiconductor channel region, and a first gate electrode contacting said first high-k dielectric portion;
forming a second field effect transistor including a second gate stack, wherein said second gate stack includes, from bottom to top, a threshold voltage adjustment oxide portion comprising said second high-k dielectric material and overlying a second semiconductor channel region, a second high-k dielectric portion comprising said first high-k dielectric material, and a second gate electrode contacting said second high-k dielectric portion.

16. The method of claim 15, further comprising forming a third field effect transistor including a third gate stack, wherein said third gate stack includes at least, from bottom to top, a third high-k dielectric portion comprising said first high-k dielectric material and a third gate electrode contacting said third high-k dielectric portion, wherein said first field effect transistor and said third field effect transistor are field effect transistors of complementary types.

17. The method of claim 15, wherein each of said first semiconductor channel region and said second semiconductor channel region are intrinsic semiconductor material portions.

18. The method of claim 11, further wherein each of said plurality of semiconductor material regions includes, from bottom to top, a doped semiconductor material portion and an intrinsic semiconductor material portion.

19. The method of claim 18, wherein a first semiconductor material region among said plurality of semiconductor material regions comprises a first semiconductor material throughout, and a second semiconductor material region among said plurality of semiconductor material regions comprises a second semiconductor material throughout, and wherein each of said first semiconductor material and said second semiconductor material is independently selected from single crystalline silicon, a single crystalline silicon-germanium alloy, a single crystalline silicon-carbon alloy, and a single crystalline silicon-germanium-carbon alloy.

20. The method of claim 11, wherein said first high-k dielectric material comprises a material selected from hafnium oxide, zirconium oxide, tantalum oxide, titanium oxide, silicates of thereof, and alloys thereof, and wherein said second high-k dielectric material comprises a material selected from an oxide of a Group IIA element, an oxide of a Group IIIB element, and alloys thereof.
